(19) United States
(12) Patent Application Publication
(10) Pub. No.: US 2016/0007495 A1
(43) Pub. Date: Jan. 7, 2016

(54) ASSEMBLY FOR ATTACHING A CIRCUIT BOARD TO A HOUSING

(71) Applicant: GOOGLE TECHNOLOGY HOLDINGS LLC, MOUNTAIN VIEW, CA (US)

(72) Inventor: Allen B. McKittrick, Grayslake, IL (US)

(21) Appl. No.: 14/322,295

(22) Filed: Jul. 2, 2014

(51) Int. Cl. H05K 7/02; H05K 1/02; G06F 1/16

(52) U.S. Cl. CPC H05K 7/02; G06F 1/1613; H05K 1/02; H05K 2201/09063

(57) ABSTRACT

The present invention provides an assembly for attaching a circuit substrate to a housing. The assembly includes a fastener having a first end and a second end opposite the first end, where the first end is larger than a second end. The assembly further includes a circuit substrate including a through hole having a first opening on a first side of the circuit substrate and a second opening on a second side of the circuit substrate, the through hole for receiving the fastener. The assembly still further includes a mounted structure attached to the circuit substrate, which at least partially covers the second opening of the through hole on the second side of the circuit substrate, wherein the mounted structure restricts the size of an exposed portion of the second opening of the through hole. The second end of the fastener, which is received in the through hole of the circuit substrate is sized to extend through the through hole, as well as the restricted size of the exposed portion of the second opening restricted by the mounted structure. The larger first end of the fastener is sized to extend through the through hole, but not through the restricted size of the exposed portion of the second opening. The assembly further includes a housing having a boss adapted and aligned for receiving the second end of the fastener after the second end of the fastener has been received by the through hole of the circuit substrate, and extends therethrough, wherein the boss is adapted to grip the received second end of the fastener.

### FIELD OF THE INVENTION

The present invention relates generally to an assembly for attaching a circuit substrate to a housing, and more particularly, to the attachment of circuit substrate to the housing via a shield coupled to the circuit substrate.

### BACKGROUND OF THE INVENTION

There is an increasing trend with regard to personal cellular communications toward the use of smartphone devices, which in addition to allowing for voice communications, also enable more extensive data type services including text messaging and web browsing. In support of such services, there has been a corresponding desire to enlarge the screen sizes in order to support the viewing of web pages, as well as support more sophisticated graphical interfaces.

As a result of increasing screen size, device real estate previously available for keyboard interfaces often involving one or more mechanically actuated buttons have given way to virtual keys integrated into the graphical interface with the virtual buttons displayed on respective portions of the ever larger screen sizes, and a touch sensitive interface overlayed upon the display screens to detect the particular area and/or button with which the user is wanting to interact.

So while the size of the front facing of the device is being adjusted to account for a reasonably large display interface that often additionally supports touch input, there still continues to be a desire to shrink the overall size of the device in one of the other dimensions, which often entails a shrinking of the thickness of the device. However, this means that creative methods to organize and arrange the elements internal to the device are often needed to try to minimize the overall height requirements. In some instances the placement of the internal elements may be restricted by a need to provide the user with access to the various porting or interfaces associated with the corresponding components. For example, the display needs to be positioned proximate the front surface and aligned with a front lens. By way of additional example, a device such as a cellular telephone needs to support a speaker which is proximate the position at which the device will interact with the ear of the user, when the device is brought proximate the user's face, and a microphone which is proximate the position at which the device will interact with the mouth of the user. Still further, it may be desirable for the porting to additionally include a charging port, a head phone jack port, porting which supports the placement of one or more cameras, as well as their associated lenses, and potentially ports for receiving one or more forms of auxiliary storage. Still further, the internal elements can additionally include control circuitry, which is used to manage the overall functionality of the device, as well as a battery to supply power to the various other elements.

Much of the functionality, needs to be supported by various circuitry and components, which often finds its way onto a circuit substrate that needs to fit within the housing constraints. In some instances additional structure including various shields need to be mounted upon the circuit substrate. The circuit substrate, then needs to be affixed to the housing and/or other elements using some manner of attachment. The manner of attachment may similarly have space requirements that can impact the placement of other elements.

Circuit substrates are often attached to various housings using mechanical fasteners such as a screw. In such an instance, the circuit board will often include a mounting hole through which one end of the screw is received, where the received end will often extend through the mounting hole and into a reciprocal structure coupled to or integrated into the housing. One such structure can include a boss type structure, which includes a hole within which the end of the screw, which travels through the through hole of the circuit substrate can be received. The other end of the fastener will often include an enlarged portion, such as a screw head, which is sized to prevent it from traveling through the through hole, such that it can hold the circuit substrate in place against the boss type structure. In such an instance the head of the fastener sits on top of the surface of the circuit substrate, and corresponding provides an area above the circuit substrate surface that other elements can not be placed. Depending upon how the other internal elements are arranged, this can impact the overall height of the device and/or the size of the other elements, such as the size of the display relative to the overall size of the device.

Correspondingly, the present inventor has recognized that it would be beneficial to manage the structure and corresponding method of attaching the circuit substrate to the housing, where the space requirements are more beneficially arranged to minimize the impact on the overall device thickness, as well as the size of the other elements located within the device.

### SUMMARY OF THE INVENTION

The present invention provides an assembly for attaching a circuit substrate to a housing. The assembly includes a fastener having a first end and a second end opposite the first end, where the first end is larger than a second end. The assembly further includes a circuit substrate including a through hole having a first opening on a first side of the circuit substrate and a second opening on a second side of the circuit substrate and a path extending between the first opening and second opening, the through hole being adapted for receiving the fastener. The assembly still further includes a mounted structure attached to the circuit substrate. The mounted structure extends to at least partially cover the second opening of the through hole on the second side of the circuit substrate, wherein the mounted structure restricts the size of an exposed portion of the second opening of the through hole on the second side of the circuit substrate, whereby the second end of the fastener received in the through hole of the circuit substrate is sized to extend through the through hole, as well as the restricted size of the exposed portion of the second opening restricted by the mounted structure, and wherein the larger first end of the fastener is sized to extend through the through hole, but not through the restricted size of the exposed portion of the second opening. The assembly further includes a housing having a boss adapted and aligned for receiving the second end of the fastener after the second end of the fastener has been received by the through hole of the circuit substrate, and extends therethrough, wherein the boss is adapted to grip the received second end of the fastener.

In at least one embodiment, the fastener includes a screw, where the first end corresponds to a head of the screw, and the second end corresponds to a shank of the screw, and wherein the head of the screw is at least partially recessed within the thickness of the circuit substrate.

In at least a further embodiment, the mounted structure is soldered to the circuit substrate; includes an open end having a perimeter, where the mounted structure is soldered to the circuit substrate at the perimeter of the open end; and includes one or more tabs extending from the perimeter of the open end, where at least one of the tabs extends to at least partially cover the second opening of the through hole on the second side of the circuit substrate.

The present invention further provides a hand-held electronic device including a housing, a circuit substrate, and an assembly for attaching the circuit substrate to the housing. The assembly includes a fastener having a first end and a second end opposite the first end, where the first end is larger than a second end. The assembly further includes a circuit substrate including a through hole having a first opening on a first side of the circuit substrate and a second opening on a second side of the circuit substrate and a path extending between the first opening and second opening, the through hole for receiving the fastener. The assembly still further includes a mounted structure attached to the circuit substrate. The mounted structure extends to at least partially cover the second opening of the through hole on the second side of the circuit substrate, wherein the mounted structure restricts the size of an exposed portion of the second opening of the through hole on the second side of the circuit substrate, whereby the second end of the fastener received in the through hole of the circuit substrate is sized to extend through the through hole, as well as the restricted size of the exposed portion of the second opening restricted by the mounted structure, and wherein the larger first end of the fastener is sized to extend through the through hole, but not through the restricted size of the exposed portion of the second opening. The assembly further includes a housing having a boss adapted and aligned for receiving the second end of the fastener after the second end of the fastener has been received by the through hole of the circuit substrate, and extends therethrough, wherein the boss is adapted to grip the received second end of the fastener.

These and other objects, features, and advantages of this invention are evident from the following description of one or more preferred embodiments of this invention, with reference to the accompanying drawings.

### BRIEF DESCRIPTION OF THE DRAWINGS

FIG. 1 is a perspective view of an exemplary electronic device, such as a hand held device;

FIG. 2 is a partial front side exploded perspective view of the hand held device, illustratred in FIG. 1;

FIG. 3 is a back side plan view of a circuit substrate with a plurality of mounted structures;

FIG. 4 is a bottom side plan view of the circuit substrate with a plurality of mounted structures, illustrated in FIG. 3; and

FIG. 5 is a partial cross-sectional view of an assembly for attaching the circuit substrate to the housing.

### DETAILED DESCRIPTION OF THE PREFERRED EMBODIMENT(S)

While the present invention is susceptible of embodiment in various forms, there is shown in the drawings and will hereinafter be described presently preferred embodiments with the understanding that the present disclosure is to be considered an exemplification of the invention and is not intended to limit the invention to the specific embodiments illustrated.

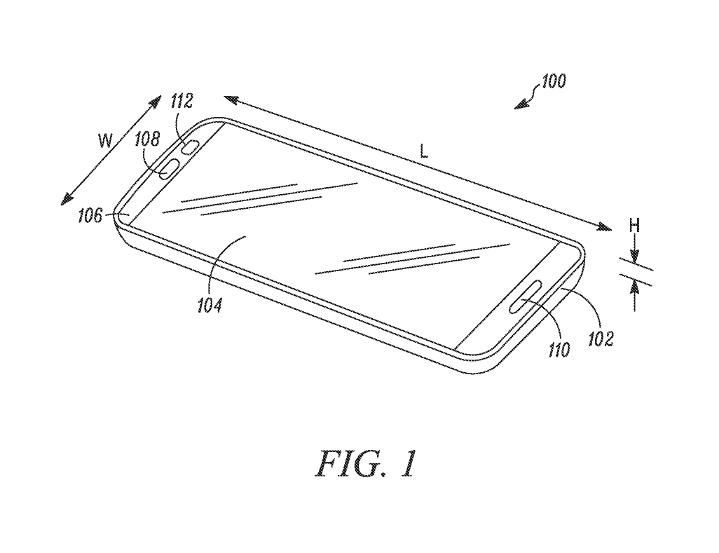

FIG. 1 illustrates a perspective view of an exemplary electronic device, such as a hand held device 100, which is suitable for use with an assembly for attaching a circuit board to a housing, which seeks to minimize the space requirements for one or more fasteners, which are used to couple a circuit board to the housing. The device is illustrated from the front side perspective.

In the illustrated embodiment, the hand held device includes a housing 102, which contains a display 104 behind a top lens 106, where the top lens 106 has openings for a speaker 108, a microphone 110, and a front facing camera 112. In the exemplary embodiment the display 104 is intended to incorporate a touch sensitive interface for use by the user in interacting with one or more displayed elements. The illustrated device, while suitable for use as a cellular radio frequency smartphone, could also be suitable for other types of electronic devices including other types of wireless communication device, media (i.e., music, video) players, personal digital assistants, portable video gaming devices, cameras, and/or remote controls. The electronic device may also be a user input subassembly of some other equipment, like an appliance or other machine.

The speaker 108 and microphone 110 are arranged to be proximate the user's ear and the user's mouth, respectively, when the device is brought into proximity to the user's face in support of voice communications. The front facing camera can be used to image the user while interacting with the touch screen interface of the device, and could be used to support a video chat type feature. Presumably, the image of the other party with which the user is communicating could be presented via the display 104. The device 100 could further include a rear facing camera (not shown), which would enable the user to capture images in the direction that the user is facing, when interacting with the touch screen interface.

The device could further incorporate a proximity sensor, not shown, for use in detecting the presence of the device proximate a surface, such as the surface of a user's face. Alternatively, the front facing camera 112 or the display 104 incorporating touch sensitive features might be used to detect the proximity of another object. While not shown, the device could support other forms of porting, such as ports for a wired connection, such as for audio (i.e. head phone jack), communications and/or charging (i.e. universal serial bus port). The device could further include ports for receiving one or more forms of auxiliary storage and/or smartcards, such as a secure digital (SD) memory card or one or more subscriber identity modules (SIM).

Enhanced data services, such as web browsing, associated with smartphones, as well as enhanced graphical user interfaces, including touch sensitive interfaces, make beneficial the use of larger higher resolution displays. As such, many similar type devices have followed the trend toward relatively larger dimension in the length (L) and width (W) direction, but in an attempt to minimize the overall size, several manufacturers have attempted to minimize the height (H), which is sometimes referred to as the device thickness.

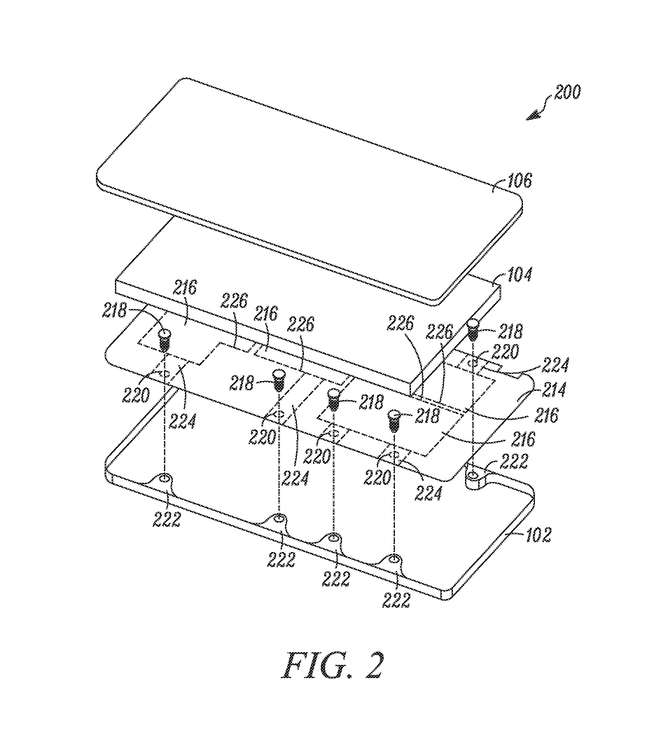

FIG. 2 illustrates a partial front side exploded perspective view 200 of the hand held device 100, illustrated in FIG. 1. In addition to the housing 102, the display 104, and the lens 106, the exploded view further illustrates a circuit substrate 214, such as a printed circuit board (PCB); one or more structures 216 mounted to the circuit substrate, such as one or more circuit shields; and one or more fasteners 218, such as one or more screws. The mounted structures 216 are affixed to the underside of the circuit substrate 214, relative to the perspective illustrated, and as such are illustrated using dashed lines. The circuit substrate includes one or more through holes 220, through which a fastener 218 can be received. Generally, the through holes 220 are drilled all the way through the circuit substrate 214. The fasteners are adapted to extend through the through hole 220 and into one or more respective bosses 222 coupled to and/or formed into the housing 102. The bosses 222 generally have a ledge upon which the received structure such as the circuit substrate 214 can rest, as well as a hole, which extends partially into the housing 102, for receiving the end of the fastener 218 extending through the through hole 220 of the circuit substrate 214.

In the illustrated embodiment, the mounted structures 216 include one or more tabs 224, which extend from the circuit shield and can coincide with a respective through hole 220 of the circuit substrate 214. The mounted structures 216 can be soldered to the circuit substrate at the perimeter 226 of the mounted structure identified by the dashed line outline, as well as at the one or more tabs 224. The mounted structure often includes a grounded conductive metal structure that can be used to shield the underlying circuitry, electromagnetically, as well as help to physically protect any underlying circuitry. In the illustrated embodiment, the circuit substrate 214 is received by the bosses 222 via the tabs 224 of the mounted structures 216, in at least the illustrated instances.

In some instances, additional elements, while not shown in the exploded view, may additionally be present. For example, in at least one embodiment of the present invention, a battery 528 (see FIG. 5) can be located between the circuit substrate 214 and the housing 102 outside of the mounted structures 216.

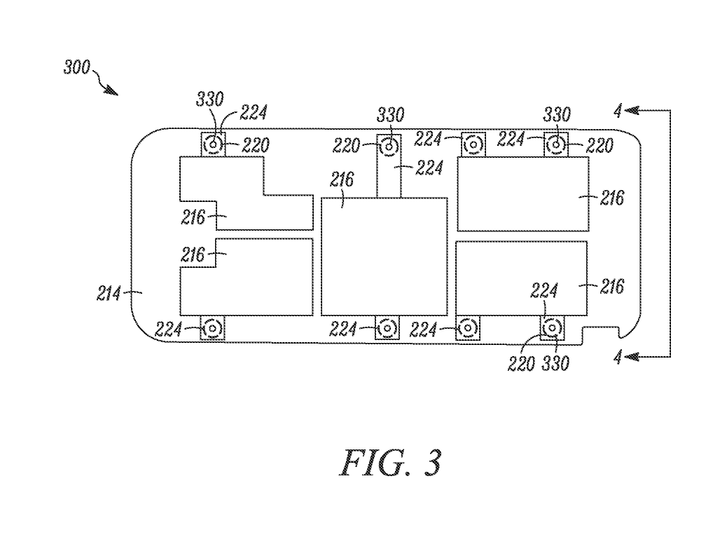

FIG. 3 illustrates a back side plan view 300 of a circuit substrate 214 with a plurality of mounted structures 216. As noted previously in connection with FIG. 2, in the illustrated embodiment, the mounted structures 216 include one or more tabs 224. In the illustrated embodiment, the tabs 224 each include a hole 330, which at least partially coincides with the through hole 220 of the circuit substrate 214. The hole 330 of the mounted structure is positioned and sized to at least partially restrict the size of the opening associated with the through hole 220 of the circuit substrate 214. While the various mounted structures serve to shield at least some of the circuit elements provided on the substrate, other areas allow for the location of connectors and/or other modules, such as the back side camera assembly, and/or one or more card reader assemblies.

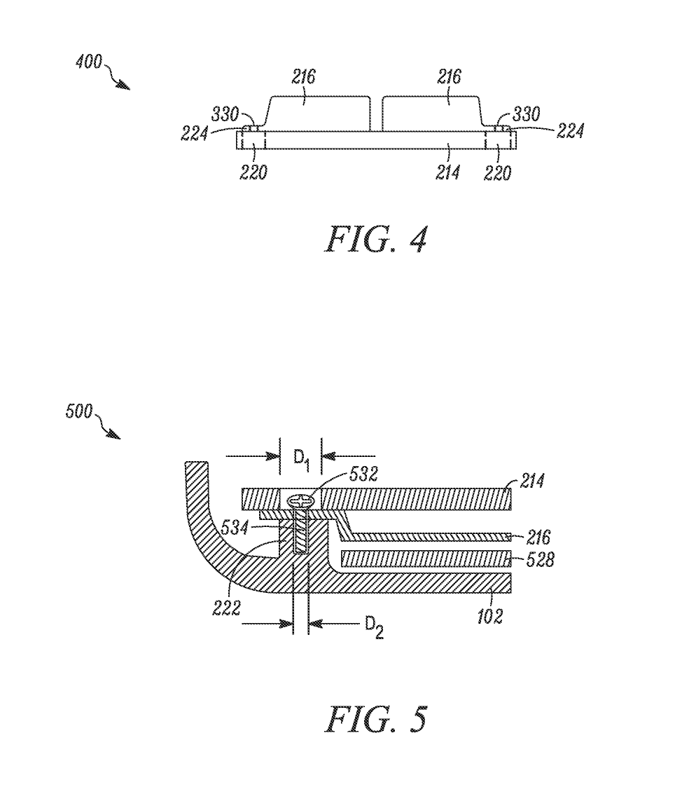

FIG. 4 illustrates a bottom side plan view 400 of the circuit substrate 214 with a plurality of mounted structures 216, illustrated in FIG. 3. As noted previously, the mounted structures can each have one or more tabs 224, which in turn can include a hole 330, which at least partially coincides with the through hole 220 of the circuit substrate 214. The present view helps to illustrate the restricted size of hole 330 relative to through hole 220. Such a sizing for hole 330 is intended to allow the fastener to only partially extend through the hole, where the sizing of through hole 220 is adapted to allow a fastener 218 to extend more fully through the hole, if it had not interacted with the more restricted size of hole 330. This allows the end of a fastener having a larger size to be received at least partially within the through hole 220, but still provides attached structure in the form of the mounted structure 216 firmly attached to the circuit substrate 214, which precludes the larger end of the fastener 218 from extending all the way through. In this way, the larger end can be received at least partially within the thickness of the circuit substrate, thereby avoiding the full height of the larger end of the fastener 218 from needing to reside above the circuit substrate 214. In at least some embodiments, the larger end of the fastener 218 may be contained completely within the through hole 220. In the illustrated embodiment, this allows the display to extend further toward the edge of the housing without having to be additionally raised relative to the front side surface of the circuit substrate 214 to avoid the full height of the larger end of the fastener 218.

FIG. 5 illustrates a partial cross-sectional view of an assembly for attaching the circuit substrate to the housing. The present view more clearly illustrates the fastener 218 relative to the through hole 220 of the circuit substrate 214, and the hole 330 associated with the one or more tabs 224 of the one or more mounted structures 216. In the illustrated embodiment, the fastener 218 is a screw. The screw has a first end, and a second end opposite the first end, where the first end is larger than the second end. In the case of a screw, the first end corresponds to the head 532 of the screw, and the second end corresponds to the shank 534.

While the through hole 220 of the circuit substrate 214 is sized to receive either the head 532 of the screw or the shank 534 of the screw, the hole 330 of the mounted structure is sized to preclude the head 532 of the screw from passing through. In this way, the circuit substrate 214 can be attached to the housing 102 via the mounted structures 216 without necessarily directly interacting with the circuit substrate 214. Furthermore, as noted above, at least a portion of the head 532 of the screw can be received within the through hole 220, thereby reducing the portion that might extend above the surface of the circuit substrate 214. In at least some instances, the height of the head 532 of the screw may be less than or equal to the thickness of the circuit substrate 214, thereby enabling the head of the screw to be more completely received and maintained within the through hole of the circuit substrate.

In the illustrated embodiment, the through hole 220 has a diameter D1, which is larger than the diameter, D2, of the hole 330 of the mounted structure 216. The shank 534 of the screw is received by the boss 222 of the housing 102. The hole within the boss 222, which receives the shank of the screw will generally either have a complementary internal thread, or will be made of a softer material and sized such that the threads of the screw can cut into the material. In this way, a circuit substrate can be attached to a housing, which offers greater flexibility in the sizing and positioning of other elements.

While the preferred embodiments of the invention have been illustrated and described, it is to be understood that the invention is not so limited. Numerous modifications, changes, variations, substitutions and equivalents will occur to those skilled in the art without departing from the spirit and scope of the present invention as defined by the appended claims.

What is claimed is:

1. An assembly for attaching a circuit substrate to a housing, said assembly comprising:
a fastener having a first end and a second end opposite the first end, where the first end is larger than a second end;
a circuit substrate including a through hole having a first opening on a first side of the circuit substrate and a second opening on a second side of the circuit substrate and a path extending between the first opening and second opening, the through hole for receiving the fastener;
a mounted structure attached to the circuit substrate, which extends to at least partially cover the second opening of the through hole on the second side of the circuit substrate, wherein the mounted structure restricts the size of an exposed portion of the second opening of the through hole on the second side of the circuit substrate, whereby the second end of the fastener received in the through hole of the circuit substrate is sized to extend through the through hole, as well as the restricted size of the exposed portion of the second opening restricted by the mounted structure, and wherein the larger first end of the fastener is sized to extend through the through hole, but not through the restricted size of the exposed portion of the second opening; and
a housing having a boss adapted and aligned for receiving the second end of the fastener after the second end of the fastener has been received by the through hole of the circuit substrate, and extends therethrough, wherein the boss is adapted to grip the received second end of the fastener.

2. An assembly in accordance with claim 1, wherein the fastener includes a screw, where the first end corresponds to a head of the screw, and the second end corresponds to a shank of the screw.

3. An assembly in accordance with claim 2, wherein the shank of the screw includes a helical ridge adapted to mate with a complementary internal thread or cut into a softer material, associated with at least one of the restricted size of the mounted structure and the boss of the housing.

4. An assembly in accordance with claim 2, wherein the head of the screw is at least partially recessed within the thickness of the circuit substrate.

5. An assembly in accordance with claim 1, wherein when the circuit substrate is attached to the housing, the second end of the fastener is adapted to enter the first opening of the through hole of the circuit substrate and exit through the second opening of the through hole of the circuit substrate before the second end of the fastener is received by the boss of the housing, whereby as the second end of the fastener is received by the boss of the housing, the first end of the fastener is prevented from passing through the through hole when it interacts with the restricted size of the exposed portion of the second opening restricted by the mounted structure.

6. An assembly in accordance with claim 1, wherein the circuit substrate is a printed circuit board.

7. An assembly in accordance with claim 6, wherein the through hole of the circuit substrate is a hole drilled through the printed circuit board.

8. An assembly in accordance with claim 1, wherein the mounted structure includes a circuit shield.

9. An assembly in accordance with claim 1, wherein the mounted structure is soldered to the circuit substrate.

10. An assembly in accordance with claim 9, wherein the mounted structure includes an open end having a perimeter, and where the mounted structure is soldered to the circuit substrate at the perimeter of the open end.

11. An assembly in accordance with claim 10, wherein the mounted structure includes one or more tabs extending from the perimeter of the open end, where at least one of the tabs extends to at least partially cover the second opening of the through hole on the second side of the circuit substrate.

12. An assembly in accordance with claim 1, wherein the mounted structure includes a hole at least partially aligned with the through hole of the circuit substrate.

13. An assembly in accordance with claim 12, wherein the hole of the mounted structure has a diameter which is smaller than a diameter of the through hole of the circuit substrate.

14. An assembly in accordance with claim 1, wherein the fastener couples the mounted structure to the boss of the housing.

15. An assembly in accordance with claim 1, wherein the assembly is for use in a hand-held electronic device.

16. An assembly in accordance with claim 15, wherein the hand-held device is a wireless communication device.

17. An assembly in accordance with claim 15, wherein the hand-held device includes a display coupled to the first side of the circuit substrate.

18. An assembly in accordance with claim 1, wherein the housing includes an integrated bottom and sides with a top opening.

19. An assembly in accordance with claim 18, further comprising a lens coupled to the housing, which is adapted and arranged for covering at least partially the top opening of the housing.

20. A hand-held electronic device comprising:
a housing, a circuit substrate, and an assembly for attaching the circuit substrate to the housing, said assembly including
a fastener having a first end and a second end opposite the first end, where the first end is larger than a second end;
the circuit substrate including a through hole having a first opening on a first side of the circuit substrate and a second opening on a second side of the circuit substrate and a path extending between the first opening and second opening, the through hole for receiving the fastener;
a mounted structure attached to the circuit substrate, which extends to at least partially cover the second opening of the through hole on the second side of the circuit substrate, wherein the mounted structure restricts the size of an exposed portion of the second opening of the through hole on the second side of the circuit substrate, whereby the second end of the fastener received in the through hole of the circuit substrate is sized to extend through the through hole, as well as the restricted size of the exposed portion of the second opening restricted by the mounted structure, and wherein the larger first end of the fastener is sized to extend through the through hole, but not through the restricted size of the exposed portion of the second opening; and
the housing having a boss adapted and aligned for receiving the second end of the fastener after the second end of the fastener has been received by the through hole of the circuit substrate, and extends therethrough, wherein the boss is adapted to grip the received second end of the fastener.
